(19) United States
(12) Patent Application Publication
(10) Pub. No.: US 2026/0156756 A1
(43) Pub. Date: Jun. 4, 2026

(54) METHOD FOR MANUFACTURING WIRING SUBSTRATE

(71) Applicant: IBIDEN CO., LTD., Gifu (JP)

(72) Inventors: Takenobu NAKAMURA, Gifu (JP); Toshihide MAKINO, Gifu (JP)

(73) Assignee: IBIDEN CO., LTD., Gifu (JP)

(21) Appl. No.: 19/397,237

(22) Filed: Nov. 21, 2025

(30) Foreign Application Priority Data
Dec. 2, 2024 (JP) 2024-209667

(51) Int. Cl. H05K 3/00; H05K 1/03; H05K 1/11

(52) U.S. Cl. CPC H05K 3/0029; H05K 1/0306; H05K 1/116; H05K 2201/094; H05K 2201/09481; H05K 2201/09527; H05K 2201/09536

(57) ABSTRACT

A method for manufacturing a wiring substrate includes irradiating target regions in a glass substrate multiple times with laser light such that modified portions are formed in the glass substrate, and etching the modified portions formed in the glass substrate such that the modified portions are removed from the substrate and that through holes are formed in the target regions, respectively. The irradiating the target regions includes irradiating a first target region with laser light, and irradiating a second target region with laser light after irradiation of the first target region such that the second target region is a target region other than an adjacent target region that is adjacent to the first target region.

### CROSS-REFERENCE TO RELATED APPLICATIONS

The present application is based upon and claims the benefit of priority to Japanese Patent Application No. 2024-209667, filed Dec. 2, 2024, the entire contents of which are incorporated herein by reference.

### BACKGROUND OF THE INVENTION

### Field of the Invention

The present invention relates to a method for manufacturing a wiring substrate.

### Description of Background Art

Japanese Patent Application Laid-Open Publication No. 2022-137321 describes a method for forming holes in a glass substrate. The entire contents of this publication are incorporated herein by reference.

### SUMMARY OF THE INVENTION

According to one aspect of the present invention, a method for manufacturing a wiring substrate includes irradiating target regions in a glass substrate multiple times with laser light such that modified portions are formed in the glass substrate, and etching the modified portions formed in the glass substrate such that the modified portions are removed from the substrate and that through holes are formed in the target regions, respectively. The irradiating the target regions includes irradiating a first target region with laser light, and irradiating a second target region with laser light after irradiation of the first target region such that the second target region is a target region other than an adjacent target region that is adjacent to the first target region.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate manufactured using a method for manufacturing a wiring substrate according to an embodiment of the present invention;

FIG. 2A is a cross-sectional view illustrating an example of a manufacturing process of a wiring substrate according to an embodiment of the present invention;

FIG. 2B is a cross-sectional view illustrating an example of a manufacturing process of a wiring substrate according to an embodiment of the present invention;

FIG. 2C is a cross-sectional view illustrating an example of a manufacturing process of a wiring substrate according to an embodiment of the present invention;

FIG. 2D is a cross-sectional view illustrating an example of a manufacturing process of a wiring substrate according to an embodiment of the present invention;

FIG. 2E is a cross-sectional view illustrating an example of a manufacturing process of a wiring substrate according to an embodiment of the present invention;

FIG. 2F is a cross-sectional view illustrating an example of a manufacturing process of a wiring substrate according to an embodiment of the present invention;

FIG. 2G is a cross-sectional view illustrating an example of a manufacturing process of a wiring substrate according to an embodiment of the present invention;

FIG. 2H is a cross-sectional view illustrating an example of a manufacturing process of a wiring substrate according to an embodiment of the present invention;

FIG. 3A is a schematic diagram illustrating an example of a laser light irradiation pattern;

FIG. 3B is a schematic diagram illustrating an example of a laser light irradiation pattern;

FIG. 3C is a schematic diagram illustrating an example of a laser light irradiation pattern; and

FIG. 3D is a schematic diagram illustrating an example of a laser light irradiation pattern.

### DETAILED DESCRIPTION OF THE EMBODIMENTS

Embodiments will now be described with reference to the accompanying drawings, wherein like reference numerals designate corresponding or identical elements throughout the various drawings.

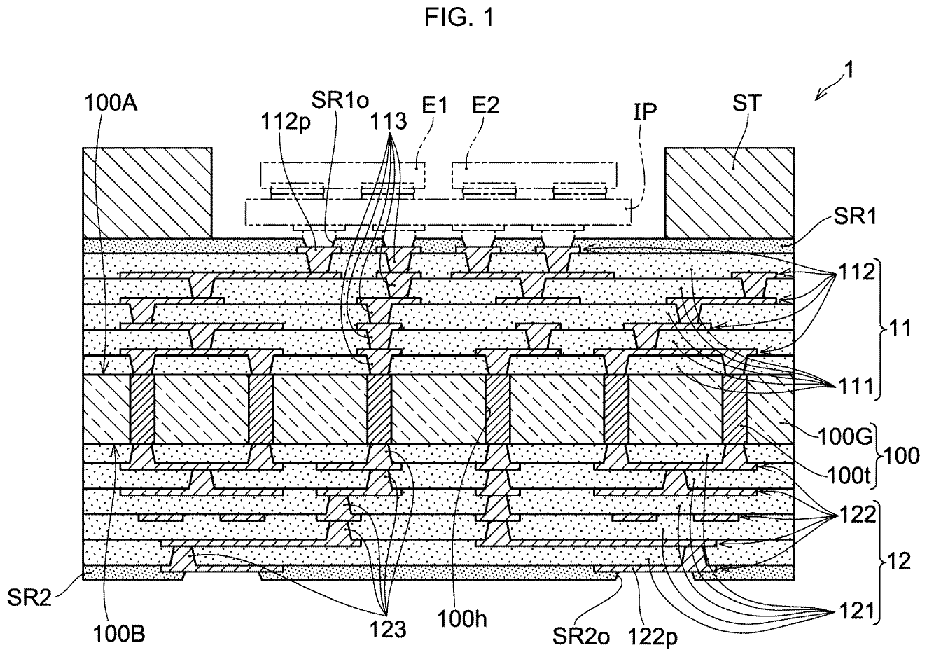

A method for manufacturing a wiring substrate according to an embodiment of the present invention is described with reference to the drawings. FIG. 1 illustrates a cross-sectional view of a wiring substrate 1, which is an example of a wiring substrate manufactured using the method for manufacturing a wiring substrate of the embodiment. The wiring substrate 1 has a core part 100 having a first surface (100A) and a second surface (100B) on an opposite side with respect to the first surface (100A). The core part 100 is composed of a glass substrate (100G) and through-hole conductors (100t) formed by filling through holes (100h) formed in the glass substrate (100G) with a conductor.

The wiring substrate of the embodiment has build-up parts that are respectively formed on both surfaces of the core part, each including 4 or more insulating layers and 4 or more conductor layers. The first surface (100A) and the second surface (100B) are each composed of a surface of the glass substrate (100G) and surfaces of the through-hole conductors (100t). A first build-up part 11 is formed on the first surface (100A). A second build-up part 12 is formed on the second surface (100B).

In the description of the wiring substrate of the present embodiment, a side farther from the core part 100 is also referred to as “upper,” “upper side,” “outer side,” or “outer,” and a side closer to the core part 100 is also referred to as “lower,” “lower side,” “inner side,” or “inner.” Further, for the insulating layers and the conductor layers, a surface facing away from the core part 100 is also referred to as an “upper surface,” and a surface facing the core part 100 side is also referred to as a “lower surface.” Therefore, for example, in the description of the structural elements of the first build-up part 11 and the second build-up part 12, a side farther from the core part 100 is also referred to as an “upper side,” “upper-layer side,” or “outer side,” or simply “upper” or “outer,” and a side closer to the core part 100 is also referred to as a “lower side,” “lower-layer side,” or “inner side,” or simply “lower” or “inner.”

The first build-up part 11 is composed of insulating layers 111 and conductor layers 112 that are alternately laminated on the first surface (100A) of the core part 100. The second build-up part 12 is composed of insulating layers 121 and conductor layers 122 that are alternately laminated on the second surface (100B) of the core part 100. Each insulating layer 111 constituting the first build-up part 11 includes via conductors 113 that connect conductors (conductor layers 112, or a conductor layer 112 and a through-hole conductor (100t)) formed on opposite sides of the insulating layer 111 in a thickness direction. Each insulating layer 121 constituting the second build-up part 12 includes via conductors 123 that connect conductors (conductor layers 122, or a conductor layer 122 and a through-hole conductor (100t)) formed on opposite sides of the insulating layer 121 in the thickness direction.

A solder resist layer (SR1) is formed on the first build-up part 11. A solder resist layer (SR2) is formed on the second build-up part 12. Openings (SR1o) are formed in the solder resist layer (SR1), and conductor pads (112p) of the outermost conductor layer 112 in the first build-up part 11 are exposed from the openings (SR1o). Openings (SR2o) are formed in the solder resist layer (SR2), and conductor pads (122p) of the outermost conductor layer 122 in the second build-up part 12 are exposed from the openings (SR2o).

The conductor pads (112p) can be connection pads used for mounting an external electronic component or the like. As illustrated, the conductor pads (112p) can be electrically and mechanically connected, for example, by a bonding material such as solder, to connection pads of an external element (IP), which can be, for example, a silicon interposer. In the illustrated example, a component (E1) and a component (E2), which are electronic components such as active components such as semiconductor integrated circuit devices or transistors (for example, logic chips or memory elements), are connected on the external element (IP). That is, electronic components can be mounted on the wiring substrate 1 via an interposer. On the other hand, the conductor pads (122p) can be connection pads used for connection to any substrate (such as an external motherboard), an electrical component, or a mechanical component (not illustrated).

In the illustrated example, a reinforcing material (ST) is provided on the solder resist layer (SR1). The reinforcing material (ST) is provided so as to surround a region where the external element (IP) is mounted while avoiding a region where the conductor pads (112p) are provided, so as not to hinder mounting of components on the surface of the wiring substrate 1. By providing the reinforcing material (ST), deformation such as warpage or bending of the wiring substrate 1 can be suppressed. By suppressing deformation of the wiring substrate 1, mounting of the external element (IP) on the wiring substrate 1 can be achieved with high reliability. However, the reinforcing material (ST) may be provided as needed, and the wiring substrate 1 does not necessarily need to include the reinforcing material (ST).

The glass substrate (100G) constituting the core part 100 is formed of glass selected from soda lime glass, aluminosilicate glass, borosilicate glass, fluoro glass, chalcogenide glass, alkali-free glass, and quartz glass. The glass substrate (100G) may contain, as additives, magnesium, calcium, manganese, aluminum, lead, iron, chromium, potassium, sulfur, antimony, boron, or the like.

The insulating layers 111 constituting the first build-up part 11 and the insulating layers 121 constituting the second build-up part 12 are each formed, for example, using an insulating resin such as epoxy resin, bismaleimide triazine resin (BT resin), or phenol resin. The insulating layers (111, 121) may each contain a reinforcing material (base material) such as glass fiber and/or an inorganic filler such as silica or alumina. The insulating layers (111, 121) have a thermal expansion coefficient of, for example, 15 ppm/° C. or more and 25 ppm/° C. or less.

The solder resist layers (SR1, SR2) are formed using, for example, a photosensitive epoxy resin or polyimide resin, or the like. As a material for the reinforcing material (ST), any material capable of suppressing deformation of the wiring substrate 1 may be used. A metallic material such as a copper alloy, an aluminum alloy, or an iron alloy can be used. However, it is preferable that the reinforcing material be formed of a material with high rigidity. For example, stainless steel is used.

The conductor layers (112, 122), the via conductors (113, 123), and the through-hole conductors (100t) can be formed using any metal such as copper or nickel. For example, the conductor layers (112, 122) can each be formed using a metal foil such as a copper foil and/or a metal film formed by plating or sputtering. In FIG. 1, the conductor layers (112, 122), the via conductors (113, 123), and the through-hole conductors (100t) are illustrated in a simplified manner as each having a single-layer structure for ease of viewing, but can each have a multilayer structure including two or more layers. The conductor layers (112, 122), the via conductors (113, 123), and the through-hole conductors (100t) can each have a two-layer structure including a metal film layer (for example, an electroless copper plating film) and a plating film layer (for example, an electrolytic copper plating film). The conductor layers (112, 122) included in the wiring substrate 1 are each patterned to have predetermined conductor patterns.

The through-hole conductors (100t) constituting the core part 100 connect the conductor layers 112 constituting the first build-up part 11 and the conductor layers 122 constituting the second build-up part 12. In the illustrated example, the through-hole conductors (100t) are directly connected to the via conductors 113 and thereby connected to the conductor layers 112 via the via conductors 113, and are directly connected to the via conductors 123 and thereby connected to the conductor layers 122 via the via conductors 123.

The through-hole conductors (100t) are composed of a conductive material that entirely fills the through holes (100h) formed in the glass substrate (100G). In the illustration, the through holes (100h) are formed to have substantially the same dimension in a thickness direction of the glass substrate (100G). However, the through holes (100h) (and thus the through-hole conductors (100t)) can also have a structure that is reduced in diameter toward a center portion in the thickness direction of the glass substrate (100G) from both the first surface (100A) side and the second surface (100B) side.

Here, for convenience, the term “reduced in diameter” is used. However, an opening shape of each through hole (100h) in plan view is not necessarily limited to a circular shape. The term “diameter” refers to a linear distance between two most distant points on an outer edge of an object when the object is viewed in plan view. The term “reduced in diameter” means that a linear distance between two most distant points on an outer edge in a horizontal cross section of each through hole (100h) becomes smaller. The term “in plan view” means viewing an object along the thickness direction of the wiring substrate 1 (that is, the thickness direction of the glass substrate (100G)).

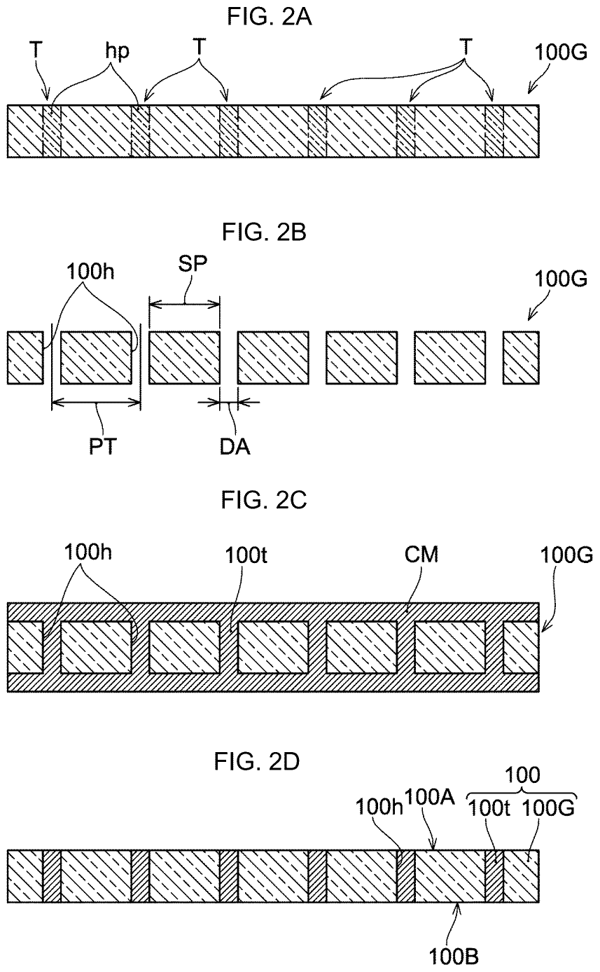

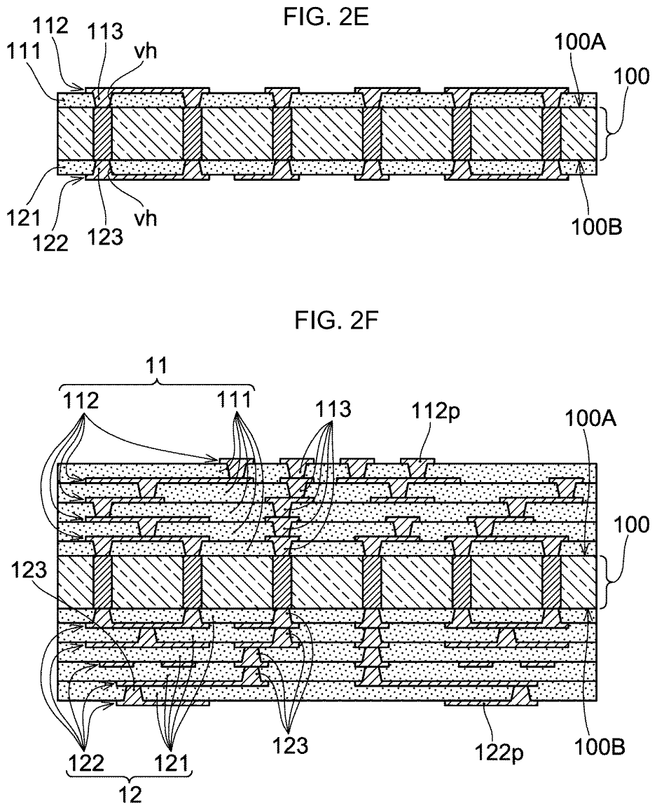

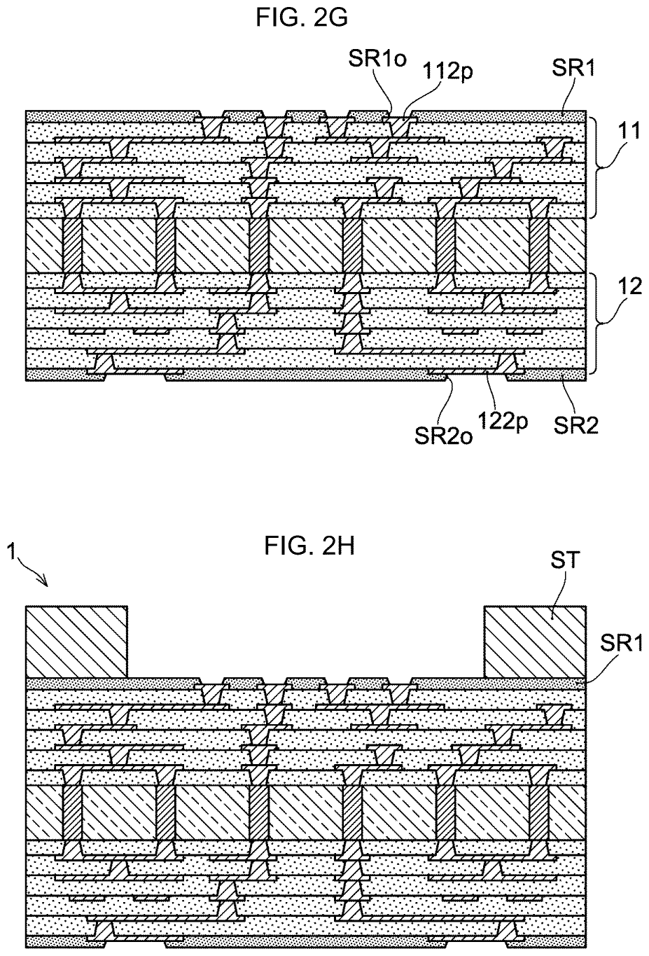

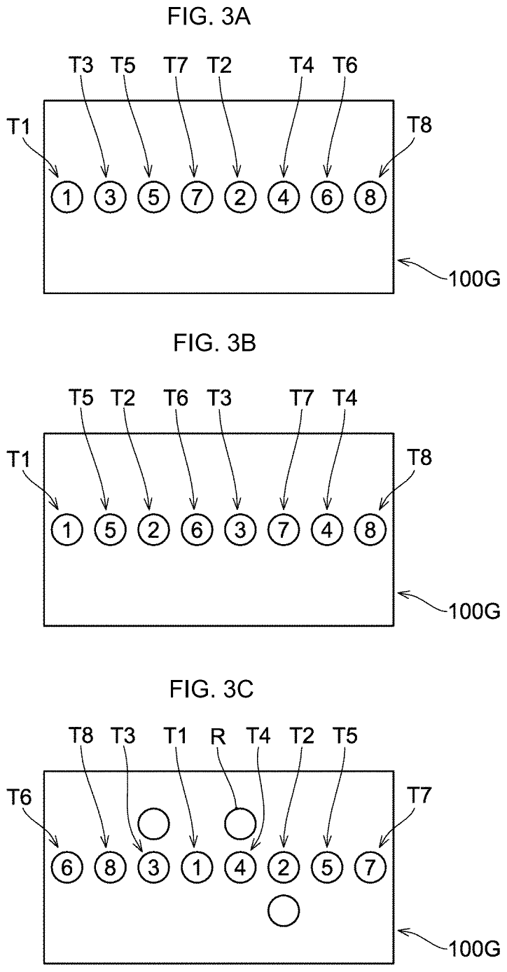

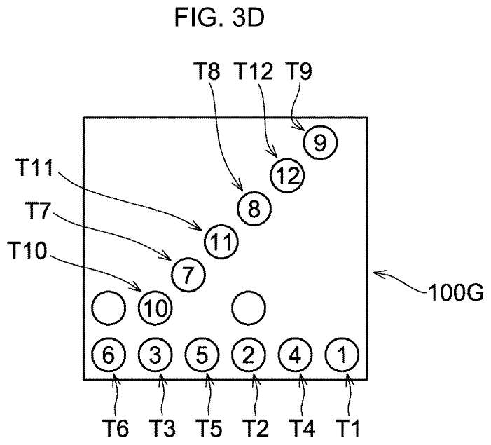

As will be described later, the through holes (100h) are formed on the glass substrate (100G) in a predetermined pattern. Positions of the through holes (100h) correspond to positions of target regions (see reference numeral symbols “T1” to “T12” in FIGS. 3A to 3D; hereinafter collectively referred to simply as the target regions (T) (see FIG. 2A)) where laser light irradiation (to be described later) is performed. As illustrated in FIGS. 3A to 3D, multiple target regions (T) are linearly positioned, and thereby, the through holes (100h) are formed in a linear formation. Here, “linearly positioned” means that the multiple target regions (T) or through holes (100h) are continuously positioned in a straight or curved line. Here, “positioned in a straight line” means that the multiple target regions (T) or through holes (100h) are positioned or formed such that one or more target regions or through holes (100h) are located on a straight line connecting a center of one target region (for example, the target region (T1) in FIG. 3A) or through hole (100h) and a center of another target region (for example, the target region (T8) in FIG. 3A) or another through hole (100h). Therefore, the centers of the multiple target regions (T) or through holes (100h) do not need to be aligned in a straight line.

In the wiring substrate 1 manufactured using the method for manufacturing a wiring substrate of the embodiment, a pitch (PT) between adjacent through holes (100h) among the multiple through holes (100h) (for example, a shortest distance between the centers of a pair of adjacent through holes (100 h)) is, for example, 250 μm or less. The multiple through holes (100h) are formed apart from each other so that spaces (SP) are formed between them. The space (SP) between adjacent through holes (100h) among the multiple through holes (100h) (for example, a shortest distance between outer edges of a pair of adjacent through holes (100 h)) is, for example, 50 μm or more, and preferably 50 um or more and 150 μm or less. Here, the “center” of each through hole (100 h) refers to a designed central position of the through hole (100h) used for forming the through hole (100h). The pitch (PT) or space (SP) between adjacent through holes (100h) in a direction in which the multiple through holes (100h) are formed (hereinafter referred to as formation direction) does not need to be constant.

Each through hole (100 h) has a diameter (DA) of, for example, 100 μm or more and 200 μm or less at the two surfaces (the first surface (100A) and the second surface (100B)) of the glass substrate (100G) that are orthogonal to the thickness direction. All drawings are schematic diagrams and are illustrated with dimensions different from those in an actual wiring substrate for ease of understanding.

The method for manufacturing a wiring substrate of the embodiment includes: forming multiple modified portions (hp) (see FIG. 2A) in the glass substrate (100G) by irradiating laser light multiple times onto the multiple target regions (T) that are linearly positioned; and forming multiple through holes (100h) in the multiple target regions (T) by removing the multiple modified portions (hp) by etching.

In the following, the method for manufacturing a wiring substrate, which includes forming the modified portions (hp) and forming the through holes (100h) is described with reference to FIGS. 2A to 2H, using a case where the wiring substrate 1 illustraed in FIG. 1 is manufactured as an example. In FIGS. 2A to 2H, as in FIG. 1, the conductor layers are simplified in structure and illustrated as each having a single-layer structure.

First, as illustrated in FIG. 2A, the glass substrate (100G) is prepared. As the glass substrate (100G), for example, a plate material made of glass selected from soda lime glass, aluminosilicate glass, borosilicate glass, fluoro glass, chalcogenide glass, alkali-free glass, and quartz glass may be prepared.

Laser is irradiated multiple times onto the target regions (T) of the glass substrate (100G), thereby forming the multiple modified portions (hp) (see FIG. 2A). Here, the target regions (T) are regions of the glass substrate (100G) where the through holes (100h) are to be formed. As the laser light, helium-neon lasers, argon ion lasers, excimer lasers, various YAG lasers, and the like may be used. Each modified portion (hp) is a portion in which the glass structure has been altered, and it is more easily removed than the surrounding unmodified portions by subsequent etching. Details of the formation of the modified portions (hp) by laser light irradiation will be described later.

Next, the multiple modified portions (hp) are removed by etching, and the multiple through holes (100h) are formed in the multiple target regions (T) (see FIG. 2B). The modified portions (hp) are removed using an etching solution containing, for example, an aqueous hydrofluoric acid solution. Specifically, the modified portions (hp) are removed by immersing the glass substrate (100G), in which the modified portions (hp) have been formed, in an etching solution containing, for example, an aqueous hydrofluoric acid solution. The concentration of the aqueous hydrofluoric acid solution is appropriately adjusted so that etching proceeds sufficiently. Further, from a point of view of promoting etching, hydrochloric acid and/or nitric acid may be included in the etching solution, and ultrasonic waves may be propagated to an etching bath during etching of the glass substrate (100G). As illustrated in FIG. 2B, the through holes (100h) are formed in the portions from which the modified portions (hp) have been removed.

Next, as illustrated in FIG. 2C, the through holes (100h) are filled with a conductive material (CM). The conductive material (CM) is formed so as to completely fill the through holes (100h) and completely cover the two surfaces of the glass substrate (100G) that are orthogonal to the thickness direction. In forming the conductive material (CM), first, a metal film layer (not illustrated) is formed on inner wall surfaces of the through holes (100h) and on the two surfaces of the glass substrate (100G), for example, by electroless plating. Subsequently, a plating film layer is formed on the metal film layer by electrolytic plating using the metal film layer as a power feeding layer, and the through-hole conductors (100t) having a two-layer structure (illustrated as a single layer in the drawing) including the metal film layer and the plating film layer are formed in the through holes (100h), and the two surfaces of the glass substrate (100G) are covered with layers of the conductive material (CM) having a two-layer structure (illustrated as a single layer in the drawing) including the metal film layer and the plating film layer.

Next, the layers of the conductive material (CM) covering the two surfaces of the glass substrate (100G) that are orthogonal to the thickness direction are removed by polishing. As illustrated in FIG. 2D, the surfaces of the glass substrate (100G) and the surfaces of the through-hole conductors (100t) are exposed. The core part 100 having the first surface (100A) and the second surface (100B), which are composed of the surfaces of the glass substrate (100G) and the surfaces of the through-hole conductors (100t), is formed. The removal of the layers of the conductive material (CM) by polishing can be performed, for example, by chemical mechanical polishing (CMP).

Next, as illustrated in FIG. 2E, an insulating layer 111 is laminated on the first surface (100A) of the core part 100, and further, a conductor layer 112 is formed on the insulating layer 111. At the same time as the formation of the conductor layer 112, via conductors 113 are formed. Further, on the second surface (100B) of the core part 100, an insulating layer 121 is laminated, and a conductor layer 122 is formed on the insulating layer 121. At the same time as the formation of the conductor layer 122, via conductors 123 are formed.

The insulating layers (111, 121) are formed, for example, by thermocompression bonding of a film-shaped insulating resin (for example, epoxy resin) onto the surfaces (the first surface (100A) and the second surface (100B)) of the core part 100. The insulating layers have a thermal expansion coefficient of, for example, 15 ppm/° C. or more and 25ppm/° C. or less. Through holes (vh) are formed, for example, by irradiation with CO₂ laser light at positions in the insulating resin where the via conductors (113, 123) are to be formed. The conductor layers (112, 122) and the via conductors (113, 123) are formed by forming a metal film layer (not illustrated) on inner surfaces of the through holes (vh) and on the upper surfaces of the insulating layers (111, 121) by electroless plating or sputtering, and performing electrolytic plating using the metal film layer as a power feeding layer and using a plating resist having appropriate openings. That is, the conductor layers (112, 122) and the via conductors (113, 123) are formed using a semi-additive process (SAP) method.

Next, as illustrated in FIG. 2F, on the upper side of the first surface (100A) of the core part 100, the same processes for forming the insulating layer 111, the conductor layer 112, and the via conductors 113 described above are repeated three or more times, and the first build-up part 11 including four or more insulating layers 111 and four or more conductor layers 112 is formed. Further, on the upper side of the second surface (100B) of the core part 100, the same processes for forming the insulating layer 121, the conductor layer 122, and the via conductors 123 described above are repeated three or more times, and the second build-up part 12 including four or more insulating layers 121 and four or more conductor layers 122 is formed. The outermost conductor layer 112 of the first build-up part 11 is patterned to include the conductor pads (112p). The outermost conductor layer 122 of the second build-up part 12 is patterned to include the conductor pads (122p).

Next, as illustrated in FIG. 2G, the solder resist layer (SR1) is formed on the first build-up part 11, and the solder resist layer (SR2) is formed on the second build-up part 12. The solder resist layers (SR1, SR2) are each formed, for example, by forming a resin layer containing a photosensitive epoxy resin or polyimide resin or the like and performing exposure and development using a mask having appropriate opening patterns. The solder resist layers (SR1, SR2) are formed to have the openings (SR1o, SR2o) that expose the conductor pads (112p, 122p). On exposed surfaces of the conductor pads (112p, 122p), a surface protection film (not illustrated) made of Au, Ni/Au, Ni/Pd/Au, solder, or heat-resistant preflux may be formed by electroless plating, solder leveling, spray coating, or the like.

Next, as illustrated in FIG. 2H, the reinforcing material (ST) is attached onto the solder resist layer (SR1). As the reinforcing material (ST), for example, a plate-shaped stainless steel material can be used. However, a metal material other than a stainless steel material may also be used. As the reinforcing material (ST), a plate-shaped metal material is used, having a planar shape formed into a shape along a contour of a region where a component is mounted on the wiring substrate 1 by punching or laser processing. The plate-shaped reinforcing material (ST) is bonded to the solder resist layer (SR1), for example, via a thermosetting adhesive (not illustrated). Through the above processes, the wiring substrate 1 is completed.

Next, details of the formation of the modified portions (hp) by laser light irradiation are described using FIGS. 3A to 3D.

The multiple modified portions (hp) in the multiple target regions (T) are formed by irradiating the multiple target regions with laser light multiple times in a predetermined order. Specifically, forming the modified portions includes irradiating a first target region among the multiple target regions with laser light (hereinafter referred to as a first laser light irradiation process), and irradiating a second target region with laser light following the irradiation of the first target region (hereinafter referred to as a second laser light irradiation process). The second target region is a target region other than an adjacent target region adjacent to the first target region (hereinafter referred to as a non-adjacent target region). As described above, by irradiating the second target region, which is a non-adjacent target region, with laser light following the first target region, crack occurrence around the through holes (100h) is suppressed. Unlike the embodiment, when laser light is continuously irradiated onto two adjacent target regions, in other words, when another modified portion is formed in an adjacent target region immediately after a modified portion is formed in one target region, stress accumulates between the two modified portions that are continuously modified by laser light irradiation. It is thought that due to stress accumulation, cracks are likely to occur in the glass substrate during laser light irradiation, or during etching or formation of the through-hole conductors, or further, during reliability tests required for the substrate. In contrast, in the embodiment, by performing laser light irradiation on a second target region, which is a non-adjacent target region, after a first target region, stress accumulation in the glass substrate (100G) is suppressed, and crack occurence is suppressed.

In the present specification, the terms “first” and “second” in the “first laser light irradiation process” and the “second laser light irradiation process” refer to the first and second of any two laser light irradiations among multiple laser light irradiation processes for irradiating the multiple target regions (T). Therefore, the first laser light irradiation process does not mean the first laser light irradiation among the multiple laser light irradiation processes, but merely indicates a relative order with respect to the second laser light irradiation process. For example, the first laser light irradiation process may be the third laser light irradiation among the multiple laser light irradiations, and the second laser light irradiation process may be the fourth laser light irradiation. The first laser light irradiation process and the second laser light irradiation process indicate a relative order among the irradiations on the multiple target regions (T) that are linearly positioned. Therefore, irradiation on a region other than the multiple target regions (T) that are linearly positioned (for example, a region (R) in FIG. 3C) may be performed between the first laser light irradiation process and the second laser light irradiation process.

The first target region is one target region that is irradiated in the first laser light irradiation process among the multiple target regions that are linearly positioned along a predetermined formation direction. The second target region is another target region that is irradiated in the second laser light irradiation process among the multiple target regions that are linearly positioned. The second target region is a non-adjacent target region that is not adjacent to the first target region, in the formation direction of the target regions (T).

In the embodiment, as illustrated in FIGS. 3A to 3D, in all laser light irradiations, among two consecutive laser light irradiations, the latter laser light irradiation is performed on a target region other than an adjacent target region that is adjacent to a target region where the former laser light irradiation is performed. In this case, crack occurrence is suppressed in all of the target regions (T) that are linearly positioned. However, not in all laser light irradiations but in some laser light irradiations, the latter laser light irradiation may be performed on a non-adjacent target region that is not adjacent to the target region where the former laser light irradiation is performed. Even in this case, crack occurrence is suppressed in some of the target regions.

The order of laser light irradiations onto the multiple target regions (T) is not particularly limited. For example, the laser light irradiations are performed in the order illustrated in FIG. 3A. In FIG. 3A, the numbers displayed in the multiple target regions (T) indicate the order of the irradiations. In the example illustrated in FIG. 3A, among two consecutive laser light irradiations, the latter laser light irradiation is performed on a target region that is shifted by 3 or more positions in the formation direction with respect to the target region where the former laser light irradiation is performed (with two or more target regions interposed therebetween). For example, in FIG. 3A, after the first laser light irradiation is performed on the target region (T1), the second laser light irradiation is performed on the target region (T2) that is shifted by four positions in a first direction (rightward in FIG. 3A) with respect to the target region (T1) in the formation direction. Next, the third laser light irradiation is performed on the target region (T3) that is shifted by three positions in a second direction (leftward in FIG. 3A) with respect to the target region (T2) in the formation direction. In this case, since two consecutive laser light irradiations are performed at positions shifted by three or more positions, stress accumulation is suppressed, and crack occurrence in the glass substrate (100G) is further suppressed.

In the example illustrated in FIG. 3B, two or more laser light irradiations are performed on target regions other than adjacent target regions between a laser light irradiation on a first target region and a laser light irradiation on an adjacent target region that is adjacent to the first target region. Specifically, as illustrated in FIG. 3B, the fifth laser light irradiation is performed on the target region (T5) adjacent to the target region (T1) where the first laser light irradiation is performed, and three other laser light irradiations are performed on other target regions between the laser light irradiations on the adjacent target regions (T1, T5). Further, between the target region (T2) where the second laser light irradiation is performed and the adjacent target region (T5), two other laser light irradiations are performed, and between the target region (T2) where the second laser light irradiation is performed and the adjacent target region (T6), three other laser light irradiations are performed. In other target regions as well, two or more other laser light irradiations are performed between the laser light irradiations on adjacent target regions. In this case, before a laser light irradiation is performed on an adjacent target region, two or more laser light irradiations are performed on non-adjacent target regions. Therefore, stress accumulation is further suppressed, and crack occurrence in the glass substrate (100G) is further suppressed. In the example illustrated in FIG. 3B, the target region irradiated in a subsequent laser light irradiation process (for example, the target region (T2) where the second laser light irradiation is performed) is positioned at a location shifted by two positions in the first direction (rightward direction in FIG. 3B) in the formation direction with respect to the target region where the preceding laser light irradiation is performed (for example, the target region (T1) where the first laser light irradiation is performed). When there is no target region located at a position shifted by two positions in the first direction with respect to an already irradiated target region (for example, after the laser light irradiation on the target region (T4) in FIG. 3B), the process returns to an unirradiated target region on the second direction side in the formation direction (for example, the target region (T5)) to perform laser light irradiation. After that, similarly, the process moves to a target region shifted by two positions in the first direction in the formation direction to perform laser light irradiation.

As illustrated in FIG. 3C, laser light irradiation may be performed randomly. Laser light irradiation may also be performed on a region (R) located outside the linearly positioned target regions (T1-T8), as illustrated in FIG. 3C. For example, laser light irradiation may be performed on the region (R) between the first laser light irradiation on the target region (T1) and the second laser light irradiation on the target region (T2).

FIG. 3D illustrates an example in which linearly positioned target regions (T1-T12) are positioned in intersecting linear patterns. In this way, the method of the embodiment may be structured such that one set of linearly positioned target regions (T1-T6) and another set of linearly positioned target regions (T7-T12) are continuously irradiated with laser light. In the example illustrated in FIG. 3D, one set of linearly positioned target regions (T1-T6) and another set of linearly positioned target regions (T7-T12) are positioned non-perpendicularly. However, the target regions (T) may be positioned such that, for example, one set of linearly positioned target regions and another set of linearly positioned target regions are positioned orthogonally to each other. Although not illustrated, the target regions may also be positioned in a loop shape, such as a rectangular frame shape formed by four sets of linearly positioned target regions.

A method for manufacturing a wiring substrate according to an embodiment of the present invention includes: forming multiple modified portions in a glass substrate by irradiating, multiple times, multiple linearly positioned target regions with laser light; and forming multiple through holes in the multiple target regions by removing the multiple modified portions by etching. The forming of the modified portions includes irradiating a first target region with laser light, and subsequently irradiating a second target region with laser light after the irradiation of the first target region, and the second target region is a target region other than an adjacent target region that is adjacent to the first target region.

According to an embodiment of the present invention, it is thought that crack occurrence around the through holes can be suppressed.

Obviously, numerous modifications and variations of the present invention are possible in light of the above teachings. It is therefore to be understood that within the scope of the appended claims, the invention may be practiced otherwise than as specifically described herein.

1. A method for manufacturing a wiring substrate, comprising:
irradiating a plurality of target regions in a glass substrate a plurality of times with laser light such that a plurality of modified portions is formed in the glass substrate; and
etching the plurality of modified portions formed in the glass substrate such that the plurality of modified portions is removed from the substrate and that a plurality of through holes is formed in the plurality of target regions, respectively,
wherein the irradiating the plurality of target regions includes irradiating a first target region with laser light, and irradiating a second target region with laser light after irradiation of the first target region such that the second target region is a target region other than an adjacent target region that is adjacent to the first target region.

2. The method for manufacturing a wiring substrate according to claim 1, wherein the target regions are linearly positioned in the glass substrate such that the modified portions are linearly positioned in the glass substrate.

3. The method for manufacturing a wiring substrate according to claim 1, wherein the target regions are linearly positioned in the glass substrate such that a pitch between adjacent through holes in the multiple through holes is 250 μm or less and that a space between adjacent through holes in the through holes is 50 μm or more.

4. The method for manufacturing a wiring substrate according to claim 1, wherein the irradiating the plurality of target regions includes applying a plurality of laser light irradiations on target regions other than the adjacent target region between a laser light irradiation on the first target region and a laser light irradiation on the adjacent target region that is adjacent to the first target region.

5. The method for manufacturing a wiring substrate according to claim 1, wherein the irradiating the plurality of target regions includes applying two consecutive laser light irradiations such that a former laser light irradiation is applied on the first target region and that a latter laser light irradiation is applied on the second target region.

6. The method for manufacturing a wiring substrate according to claim 2, wherein the target regions are linearly positioned in the glass substrate such that a pitch between adjacent through holes in the multiple through holes is 250 μm or less and that a space between adjacent through holes in the through holes is 50 μm or more.

7. The method for manufacturing a wiring substrate according to claim 2, wherein the irradiating the plurality of target regions includes applying a plurality of laser light irradiations on target regions other than the adjacent target region between a laser light irradiation on the first target region and a laser light irradiation on the adjacent target region that is adjacent to the first target region.

8. The method for manufacturing a wiring substrate according to claim 2, wherein the irradiating the plurality of target regions includes applying two consecutive laser light irradiations such that a former laser light irradiation is applied on the first target region and that a latter laser light irradiation is applied on the second target region.

9. The method for manufacturing a wiring substrate according to claim 3, wherein the irradiating the plurality of target regions includes applying a plurality of laser light irradiations on target regions other than the adjacent target region between a laser light irradiation on the first target region and a laser light irradiation on the adjacent target region that is adjacent to the first target region.

10. The method for manufacturing a wiring substrate according to claim 3, wherein the irradiating the plurality of target regions includes applying two consecutive laser light irradiations such that a former laser light irradiation is applied on the first target region and that a latter laser light irradiation is applied on the second target region.

11. The method for manufacturing a wiring substrate according to claim 4, wherein the irradiating the plurality of target regions includes applying two consecutive laser light irradiations such that a former laser light irradiation is applied on the first target region and that a latter laser light irradiation is applied on the second target region.

12. The method for manufacturing a wiring substrate according to claim 6, wherein the irradiating the plurality of target regions includes applying a plurality of laser light irradiations on target regions other than the adjacent target region between a laser light irradiation on the first target region and a laser light irradiation on the adjacent target region that is adjacent to the first target region.

13. The method for manufacturing a wiring substrate according to claim 6, wherein the irradiating the plurality of target regions includes applying two consecutive laser light irradiations such that a former laser light irradiation is applied on the first target region and that a latter laser light irradiation is applied on the second target region.

14. The method for manufacturing a wiring substrate according to claim 12, wherein the irradiating the plurality of target regions includes applying two consecutive laser light irradiations such that a former laser light irradiation is applied on the first target region and that a latter laser light irradiation is applied on the second target region.

15. The method for manufacturing a wiring substrate according to claim 1, wherein the target regions are linearly positioned in the glass substrate such that a pitch between adjacent through holes in the multiple through holes is 250 μm or less and that a space between adjacent through holes in the through holes is in a range of 50 μm to 150 μη.

16. The method for manufacturing a wiring substrate according to claim 1, wherein the plurality of modified portions is etched such that each of the through holes is formed to have a diameter in a range of 100 μm to 200 μm.

17. The method for manufacturing a wiring substrate according to claim 2, wherein the target regions are linearly positioned in the glass substrate such that a pitch between adjacent through holes in the multiple through holes is 250 μm or less and that a space between adjacent through holes in the through holes is in a range of 50 μm to 150 um.

18. The method for manufacturing a wiring substrate according to claim 2, wherein the plurality of modified portions is etched such that each of the through holes is formed to have a diameter in a range of 100 μm to 200 μm.

19. The method for manufacturing a wiring substrate according to claim 15, wherein the plurality of modified portions is etched such that each of the through holes is formed to have a diameter in a range of 100 μm to 200 μm.

20. The method for manufacturing a wiring substrate according to claim 17, wherein the plurality of modified portions is etched such that each of the through holes is formed to have a diameter in a range of 100 μm to 200 μm.
